(19) United States
(12) Patent Application Publication
(10) Pub. No.: US 2007/0147077 A1
(43) Pub. Date: Jun. 28, 2007

(54) Backlight source with organic light emitting layer having light emitting portions and liquid crystal display employing same

(75) Inventors: Wei Wang, Miao-Li (TW); An Shih, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/642,142

(22) Filed: Dec. 20, 2006

(30) Foreign Application Priority Data
Dec. 23, 2005 (TW) 94146351

(51) Int. Cl. F21V 7/04

(52) U.S. Cl. 362/611

(57) ABSTRACT

An exemplary backlight source (220) includes a first electrode layer (221), an organic light emitting layer (223), and a second electrode layer (222) arranged in that order from one side of the backlight source to an opposite side of the backlight source. The organic light emitting layer comprises at least two light emitting portions (2231) and a spacing portion located between the light emitting portions. Because the organic light emitting layer includes the spacing portion spacing the light emitting portions thereof, the organic light emitting layer has an increased heat radiating area. Thus, the organic light emitting layer has an improved heat radiating capability, and has a slower deterioration speed. Therefore, the backlight source has an increased useful time.

### FIELD OF THE INVENTION

The present invention relates to backlight modules those used in liquid crystal displays (LCDs), and particularly to a backlight source which includes an organic light emitting layer having at least two light emitting portions and a liquid crystal display employing the backlight source.

### GENERAL BACKGROUND

A liquid crystal display (LCD) is capable of displaying a clear and sharp image through thousands or even millions of pixels that make up the complete image. The liquid crystal display has thus been applied to various electronic equipment in which messages or pictures need to be displayed, such as mobile phones and notebook computers. However, liquid crystal molecules in the liquid crystal display do not themselves emit light. Rather, the liquid crystal molecules have to be lit up by a light source so as to clearly and sharply display text and images. The light source may be ambient light, or a backlight source attached to the liquid crystal display.

Referring to FIG. 5, a typical LCD is shown. The LCD 100 includes a liquid crystal panel 110 and a backlight source 120. The backlight source 120 includes a first electrode layer 121, an organic light emitting layer 123, and a second electrode layer 122 disposed in that order, from top to bottom. The liquid crystal panel 110 is located adjacent to the first electrode layer 121 of the backlight source 120.

The first electrode layer 121 functions as an anode, is generally made from a transparent conductive material, such as indium tin oxide (ITO) or indium zinc oxide (IZO). The organic light emitting layer 123 is monolayer or multilayer organic film, and is formed by being vapor deposited or being spun on the first electrode layer 121. The second electrode layer 122 functions as a cathode, and is generally made from a metal.

When backlight source 120 is driven by a voltage, the first electrode layer 121 injects electric holes into the organic light emitting layer 123, and the second electrode layer 122 injects electrons into the organic light emitting layer 123. The electrons and the electric holes meet and bond, thus both returning a basic state from an excited state. Energy radiates in the form of rays.

However, in order to coordinate with an emitting area of the backlight source 120, the organic light emitting layer 123 generally has a large area. As a result, the organic light emitting layer 123 radiates heat slowly, and therefore is too hot, thus accelerating a deterioration speed thereof. Therefore, the backlight source 120 has a decreased useful time, and the liquid crystal display 100 has decreased use-cost.

Therefore, what is needed, is a new backlight source that can overcome the above-described problem. What is also needed is a liquid crystal display employing the backlight source.

### SUMMARY

In one preferred embodiment, a backlight source includes a first electrode layer, an organic light emitting layer, and a second electrode layer arranged in that order from one side of the backlight source to an opposite side of the backlight source. The organic light emitting layer includes at least two light emitting portions and a spacing portion located between the light emitting portions.

Other advantages and novel features will become more apparent from the following detailed description when taken in conjunction with the accompanying drawings. In the drawings, all the views are schematic.

### BRIEF DESCRIPTION OF THE DRAWINGS

FIG. 1 is an exploded, side view of a liquid crystal display according to a first embodiment of the present invention.

FIG. 2 is an exploded, isometric view of the liquid crystal display of FIG. 1.

FIG. 3 is an exploded, side view of a liquid crystal display according to a second embodiment of the present invention.

FIG. 4 is an exploded, isometric view of the liquid crystal display of FIG. 3.

FIG. 5 is an exploded, side view of a conventional liquid crystal display.

### DETAILED DESCRIPTION OF PREFERRED EMBODIMENTS

Referring to FIG. 1, a liquid crystal display according to a first embodiment of the present invention is shown. The liquid crystal display 200 includes a liquid crystal panel 210 and a backlight source 220. The backlight source 220 includes a first electrode layer 221, an organic light emitting layer 223, and a second electrode layer 222 disposed in that order, from top to bottom. The first electrode layer 221 functions as an anode, and the second electrode 222 functions as a cathode. The liquid crystal panel 210 is located adjacent to the first electrode layer 221 of the backlight source 220.

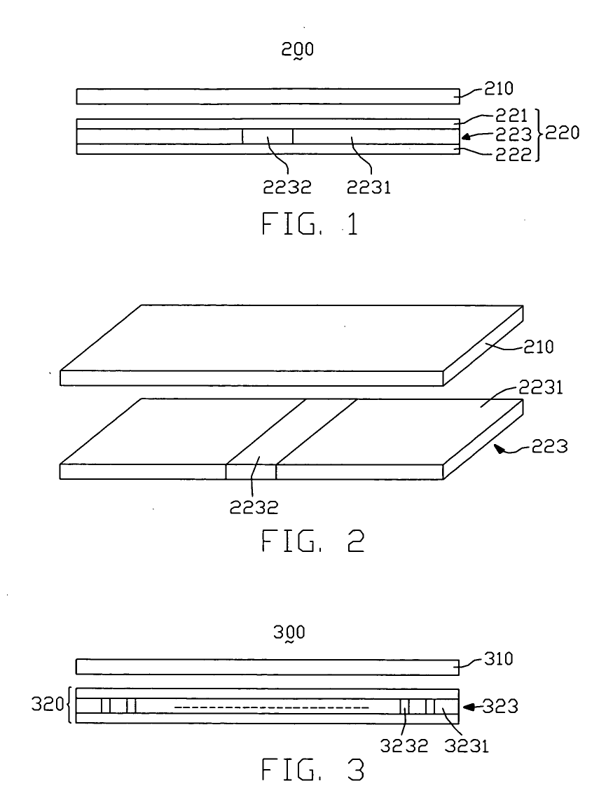

Referring also to FIG. 2, a whole area of the organic light emitting layer 223 is substantially equal to an area of the liquid crystal panel 210. The organic light emitting layer 223 includes two light emitting portions 2231 and a spacing portion 2232 between the two light emitting portions 2231 and connecting the two light emitting portions 2231. The two light emitting portions 2231 have an identical area. The spacing portion 2232 is made from a passivation material.

When backlight source 220 is driven by a voltage, the first electrode layer 221 injects electric holes into the organic light emitting layer 223, and the second electrode layer 222 injects electrons into the organic light emitting layer 223. The electrons and the electric holes meet and bond, thus both returning a basic state from an excited state. Energy radiates in the form of rays.

In summary, because the organic light emitting layer 223 includes the spacing portion 2232 spacing the two light emitting portions 2231 thereof, the organic light emitting layer 223 has an increased heat radiating area. Thus, the organic light emitting layer 223 has an improved heat radiating capability, and has a slower deterioration speed. Therefore, the backlight source 220 has an increased useful time, and therefore the liquid crystal display 200 has reduced use-cost.

Referring to FIG. 3, a liquid crystal display according to a second embodiment of the present invention is shown. The liquid crystal display 300 is similar to the liquid crystal display 200 of the first embodiment. However, the liquid crystal display 300 includes a backlight source 320 having an organic light emitting layer 323. The organic light emitting layer 323 includes a plurality of light emitting portions 3231 arranged in a matrix and a spacing portion 3232 between the light emitting portions 3231.

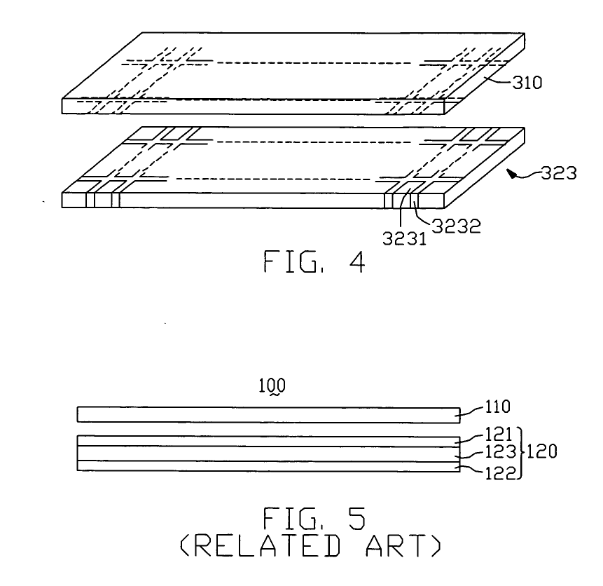

Referring also to FIG. 4, the liquid crystal panel 310 includes a plurality of pixel regions (not labeled) arranged in a matrix. Each light emitting portion 3231 corresponds to the respective pixel region, and has the same area as the respective pixel region.

Further or alternative embodiments may include the following. In one example, the first electrode layer 221 of the first embodiment functions as a cathode, and the second electrode layer 222 functions as an anode.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A backlight source comprising a first electrode layer, an organic light emitting layer, and a second electrode layer arranged from one side of the backlight source to an opposite side of the backlight source, wherein the organic light emitting layer comprises at least two light emitting portions and a spacing portion located between the light emitting portions.

2. The backlight source as claimed in claim 1, wherein the organic light emitting layer comprises two light emitting portions.

3. The backlight source as claimed in claim 1, wherein the light emitting portions have a same area.

4. The backlight source as claimed in claim 1, wherein the organic light emitting layer further comprises a plurality of light emitting portions arranged in a matrix.

5. The backlight source as claimed in claim 1, wherein the spacing portion is made from a passivation material.

6. The backlight source as claimed in claim 1, wherein the first electrode layer is an anode, and the second electrode layer is a cathode.

7. The backlight source as claimed in claim 6, wherein the first electrode is made from a transparent conductive material.

8. The backlight source as claimed in claim 7, wherein the first electrode layer is made from indium tin oxide or indium zinc oxide.

9. A liquid crystal display comprising:
a liquid crystal panel; and
a backlight source located adjacent to the liquid crystal panel, the backlight source comprising a first electrode layer, an organic light emitting layer, and a second electrode layer disposed in that order from top to bottom;
wherein the organic light emitting layer comprises at least two light emitting portions and a spacing portion located between the light emitting portions.

10. The liquid crystal display as claimed in claim 9, wherein the organic light emitting layer comprises two light emitting portions.

11. The liquid crystal display as claimed in claim 9, wherein the light emitting portions have a same area.

12. The liquid crystal display as claimed in claim 9, wherein the organic light emitting layer comprises a plurality of light emitting portions arranged in a matrix.

13. The liquid crystal display as claimed in claim 9, wherein the spacing portion is made from a passivation material.

14. The liquid crystal display as claimed in claim 9, wherein the first electrode layer is an anode, and the second electrode layer is a cathode.

15. The liquid crystal display as claimed in claim 14, wherein the first electrode is made from a transparent conductive material.

16. The liquid crystal display as claimed in claim 15, wherein the first electrode layer is made from indium tin oxide or indium zinc oxide.

17. The liquid crystal display as claimed in claim 12, wherein the liquid crystal panel comprises a plurality of pixel regions arranged in a matrix.

18. The liquid crystal display as claimed in claim 17, wherein each of the light emitting portions corresponds to a respective pixel region, and has the same area as the respective pixel region.

19. A backlight source comprising a first electrode layer, an organic light emitting layer, and a second electrode layer arranged from one side of the backlight source to an opposite side of the backlight source, wherein the organic light emitting layer is formed by a plurality of discrete emitting portions each dimensioned smaller than the first electrode layer and the second electrode layer.
